(19) United States
(12) Patent Application Publication
(10) Pub. No.: US 2017/0344055 A1
(43) Pub. Date: Nov. 30, 2017

(54) STRUCTURAL BRACE FOR ELECTRONIC CIRCUIT WITH STRETCHABLE SUBSTRATE

(71) Applicant: Intel Corporation, Santa Clara, CA (US)

(72) Inventors: Aleksandar Aleksov, Chandler, AZ (US); Javier Soto Gonzalez, Chandler, AZ (US)

(21) Appl. No.: 15/164,559

(22) Filed: May 25, 2016

(51) Int. Cl. G06F 1/16; H05K 1/03; H05K 3/32; H05K 1/18; H05K 3/22; H05K 1/02

(52) U.S. Cl. CPC G06F 1/163; H05K 3/22; H05K 1/0283; H05K 1/0296; H05K 3/32; H05K 1/0281; H05K 1/185; H05K 1/0393; H05K 2201/10522; H05K 2203/1316; H05K 2203/1327

(57) ABSTRACT

An electronic circuit may include an elastomeric substrate with an electronic die attached to the elastomer substrate at a first substrate area and one or more meander traces electrically coupled to the electronic die and encapsulated in the elastomer substrate at a second substrate area that is adjacent to the first substrate area. An inelastic, non-electronic, structural brace may be attached to the elastomeric substrate in the first substrate area.

### TECHNICAL FIELD

The present disclosure relates generally to wearable electronics and more particularly to flexible, stretchable, and wearable electronics.

### BACKGROUND

The background description provided herein is for the purpose of generally presenting the context of the disclosure. Unless otherwise indicated herein, the materials described in this section are not prior art to the claims in this application and are not admitted to be prior art by inclusion in this section.

Wearable electronics have been developed that in some embodiments are physically rigid and bulky. In other embodiments, wearable electronics may be flexible and stretchable, and so may improve upon the rigidness and bulkiness of legacy embodiments. However, the flexure and elongation of such wearable electronics may introduce reliability and/or durability issues.

### BRIEF DESCRIPTION OF THE DRAWINGS

FIG. 1 illustrates generally a block diagram of an example multilayer, flexible and stretchable (e.g., wearable) electronic circuit.

FIG. 2 illustrates generally a plan view of an example multilayer, flexible and stretchable (e.g., wearable) electronic circuit.

FIG. 3 is a cross-sectional view of an electronic circuit, which may correspond or be analogous to the electronic circuit of FIG. 2, and illustrates example embodiments of device areas and an interconnect area.

FIG. 4 is a cross-sectional view of an electronic circuit, which may generally correspond or be analogous to the electronic circuit of FIG. 3 and may further include one or more structural braces.

FIG. 5 is a top plan view of the electronic circuit of FIG. 4 illustrating structural braces of one embodiment.

FIG. 6 is a top plan view of an electronic circuit, analogous to the electronic circuit of FIG. 4, illustrating structural braces of another embodiment.

FIG. 7 is a top plan view of an electronic circuit illustrating structural braces of yet another embodiment.

FIG. 8 is a flow diagram of forming a structural brace at a device area of a wearable electronic device.

FIG. 9 is a cross-sectional view of an electronic circuit, which may generally correspond or be analogous to the electronic circuit of FIG. 3 and may further include one or more structural braces.

### DETAILED DESCRIPTION

In the following detailed description, reference is made to the accompanying drawings which form a part hereof wherein like numerals designate like parts throughout, and in which is shown by way of illustration embodiments that may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

Aspects of the disclosure are disclosed in the accompanying description. Alternate embodiments of the present disclosure and their equivalents may be devised without parting from the spirit or scope of the present disclosure. It should be noted that like elements disclosed below are indicated by like reference numbers in the drawings.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “module” may refer to, be part of, or include an Application Specific Integrated Circuit (ASIC), an electronic circuit, a processor (shared, dedicated, or group) and/or memory (shared, dedicated, or group) that execute one or more software or firmware programs, a combinational logic circuit, and/or other suitable components that provide the described functionality.

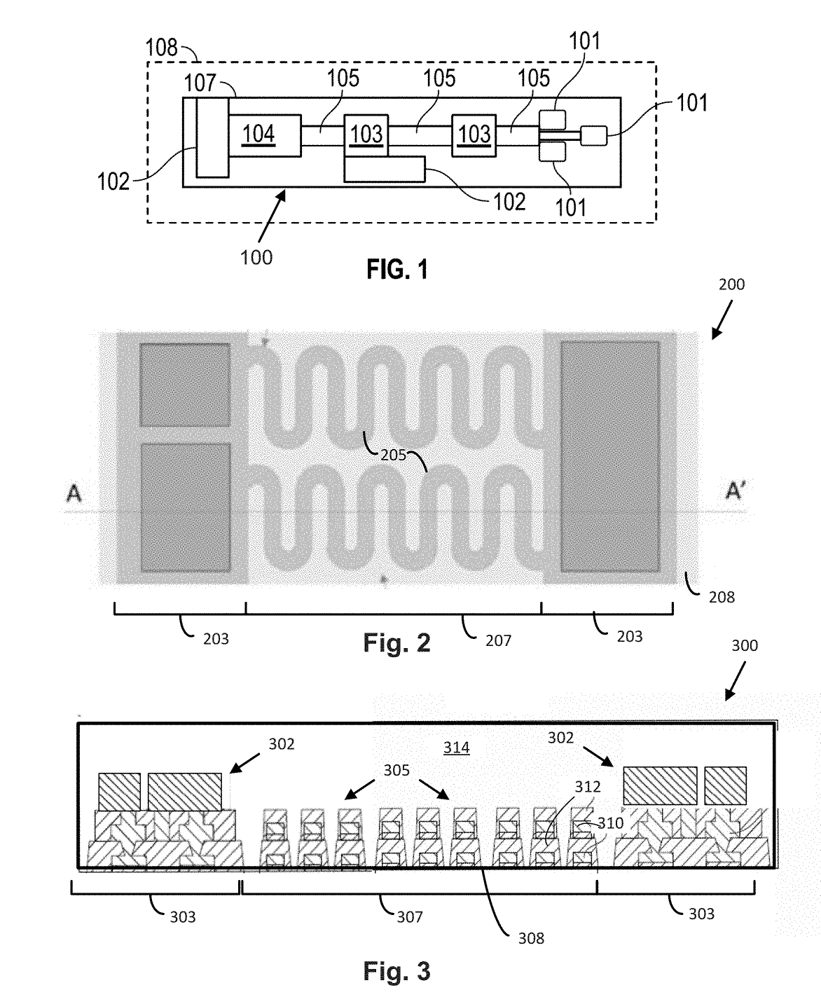

As an illustration of an operating environment of embodiments described herein, FIG. 1 is a block diagram of an example multilayer, flexible and stretchable (e.g., wearable) electronic circuit 100. In certain examples, the electronic circuit 100 may include any of one or more input/output (I/O) devices 101, one or more connectors 102, one or more device areas 103 with one or more electronic devices (described below), a power source 104, and one or more flexible and stretchable interconnects (e.g., meander traces) 105 in one or more interconnect areas 106 for making electrical connections between the various other components. Electronic circuit 100 may be formed on, applied to, and/or embedded in a flexible and/or stretchable (e.g., wearable) substrate 108, which may include one or more layers and may include or be formed of an elastomer or elastomeric material so that substrate 108 may sometimes be referred to as elastomeric substrate 108. It will be appreciated that the illustrated components and areas of electronic circuit 100, and their arrangement, are merely illustrative and that embodiments described below may include any arrangement and/or combination of such components.

In some forms, embodiments of stretchable electronic assemblies described herein may be integrated with or attached to textiles (e.g., clothing). In other forms, embodiments of stretchable electronic assemblies may be applied directly to the skin of a person or an animal or the surface of an object, as an adhesive bandage or a wrap, for example. As used herein, “stretchable” may refer to an ability to elongate in the direction of an applied force. The amount of stretching may be determined in part on the application in which a stretchable electronic assembly described herein may be used. Stretchable electronic assemblies described herein may be contrasted with electronic assemblies formed on inelastic substrates, such as conventional circuit boards.

In certain examples, the one or more input/output (I/O) devices 101 can include, but are not limited to, sensors, actuators, displays, inputs or combinations thereof. In certain examples, the sensors, actuator, displays and input devices can include a vast domain of devices including, but not limited to, multi-layered devices, displays, keyboards or combinations thereof. In certain examples, one or more connectors can include connectors for other power sources, connectors for interfacing with non-wearable components such as, but not limited to, power supply chargers, data loggers, and connectors for interconnecting one or more second, flexible and stretchable, wearable, electronic circuits.

In certain examples, the device areas 103 can include one or more electronic devices, which may include one or more processors, memory, specialized circuits, hybrid circuits, system-in-packages (SIPs), system-on-chips (SOCs), communication components, passive components, or a combination thereof. In some examples, the communication components can include wired or wireless transmitters, receivers, transceivers, or a combination thereof. In certain examples, the device areas 103 generally can include non-flexible circuit components coupled to flexible and stretchable circuit interconnects 105.

FIG. 2 illustrates generally a top plan view of an example multilayer, flexible and/or stretchable (e.g., wearable) electronic circuit 200, which may include one or more device areas 203 and one or more flexible and stretchable meander traces or interconnects 205 in one or more interconnect areas 207 (one shown) that may extend between device areas 203. Device areas 203 and interconnect areas 206 may encompass and/or be formed on and/or encapsulated in an elastomeric substrate 208. Electronic circuit 200 may be analogous to and/or include any of the components described with reference to electronic circuit 100.

FIG. 3 is a cross-sectional view of electronic circuit 300, which may correspond or be analogous to electronic circuit 200, and illustrates example embodiments of device areas 303 and an interconnect area 307. For example, devices areas 303 may include one or more electronic devices 302 that may be arranged in one or more layers and may be embedded in or otherwise attached to elastomeric substrate 308. Likewise, meander traces 305 may include one or more layers (e.g., two show), and each layer may include a conductive segment 310 and a dielectric material 312. An encapsulating elastomer 314 may provide encapsulation of devices 302 in device areas 303 and meander traces 305 in interconnect area 307.

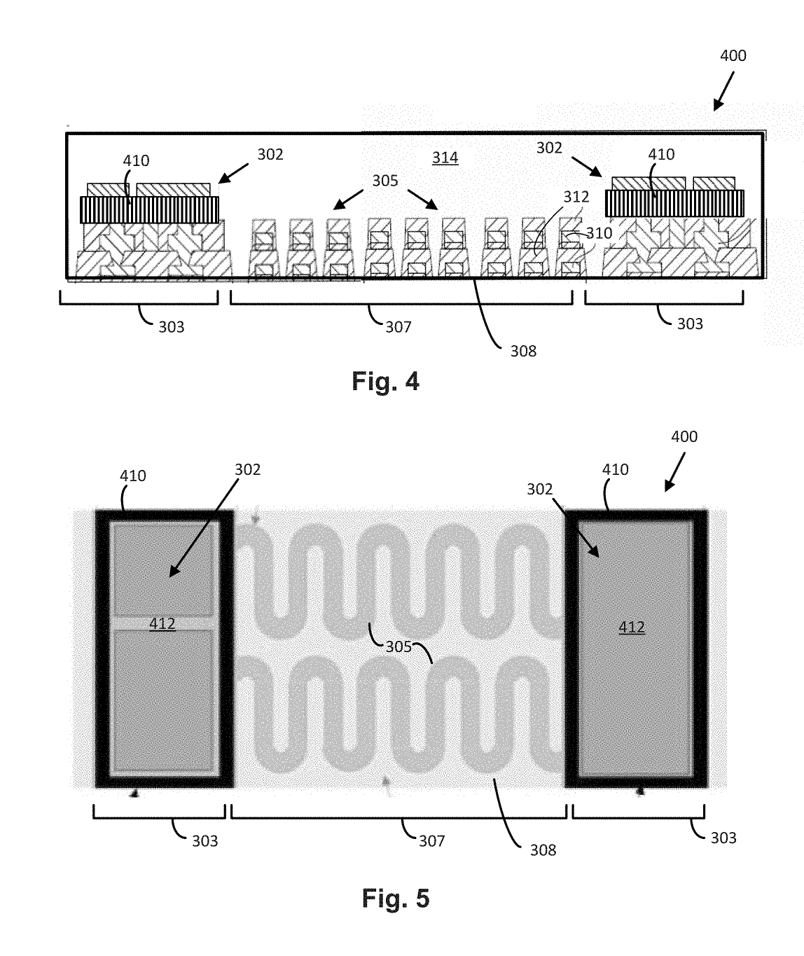

FIG. 4 is a cross-sectional view of electronic circuit 400, which may generally correspond or be analogous to electronic circuit 300 and may include common components that are indicated by common reference numerals. Electronic circuit 400 may further include one or more structural braces 410 that may be attached to electronic circuit 400 at or along one or more device areas 303. Structural braces 410 may be inelastic and non-electronic and may reinforce the device areas 303 to reduce or prevent flexing, elongation, warpage, and/or compression that may otherwise arise in connection with stretching, flexing, and/or other elastomeric motion of electronic circuit 400 or tensile, compressive and/or lateral forces applied to electronic circuit 400. In embodiments, structural braces 410 may reduce tensile stress or flexure, for example, along or within device areas 303 and/or where interconnect area 307 meets device areas 303.

FIG. 5 is a top plan view of electronic circuit 400 illustrating structural braces 410 of one embodiment. In this embodiment, each structural brace 410 may include a closed frame that may substantially bound or surround its device area 303 and may include an aperture 412 so that structural brace 410 may substantially frame device area 303.

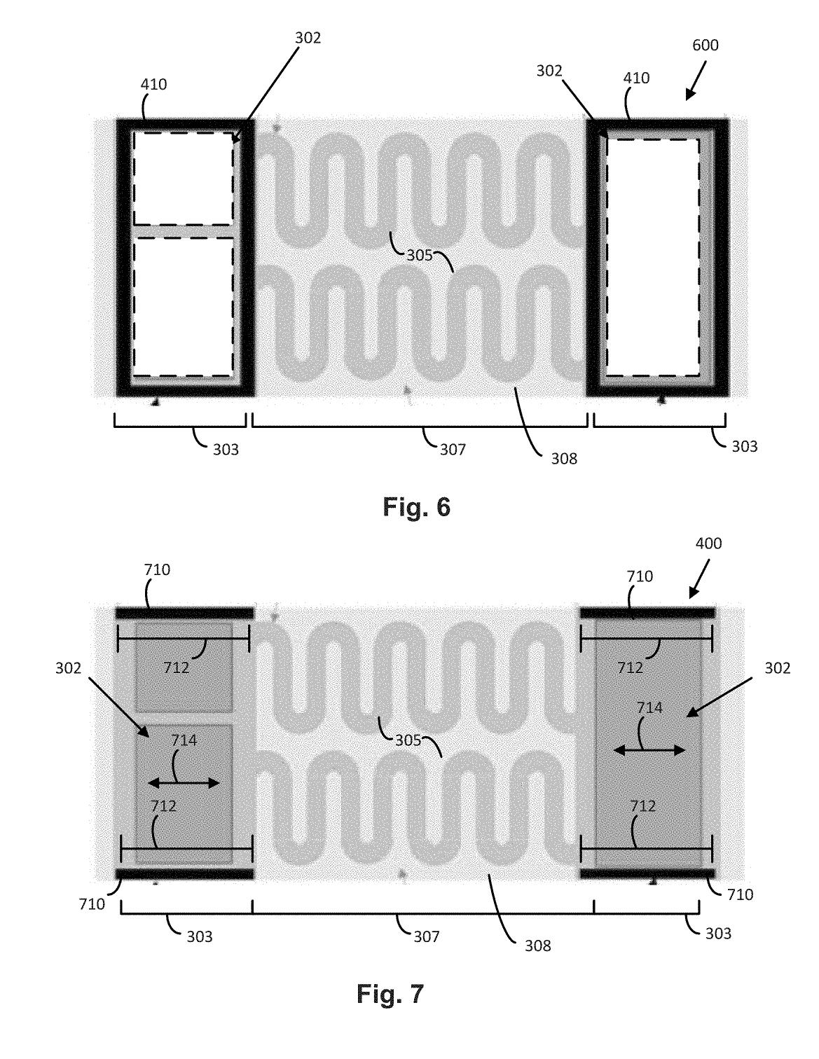

FIG. 6 is a top plan view of an electronic circuit 600, analogous to electronic circuit 400, illustrating structural braces 610 of another embodiment. In this embodiment, each structural brace 610 may be a continuous or solid region that may extend over device area 303 and may not include aperture 412 of structural brace 410. Devices 302 are outlined in dashed lines underneath structural braces 610.

FIG. 7 is a top plan view of electronic circuit 700 illustrating structural braces 710 of yet another embodiment. In this embodiment, one or more structural braces 710 may include an elongated length 712 and may extend substantially along device area 303 in a direction 714 toward interconnect area 307. In embodiments, first and second structural braces 710 may extend substantially along opposite sides of device area 303 in direction 714 in spaced-apart and parallel relation to each other, as illustrated in FIG. 7. Direction 714 may correspond to a main or predominant direction or axis of stretching of device area 303 against which structural braces 710 may provide support.

Like structural braces 410, structural braces 610, and/or 710 may be inelastic and non-electronic and may reinforce the device areas 303 to reduce or prevent flexing, elongation, and/or compression that may otherwise arise at or along devices areas 303 in connection with stretching, flexing, and/or other elastomeric motion of electronic circuit 400 or tensile, compressive and/or lateral forces applied to electronic circuit 400.

Structural braces 410, 610, and/or 710 may be formed of one or more inelastic materials and may form structural members that may be non-electronic in that structural braces 410, 610, and/or 710 are not circuit components of electronic circuit 400. In embodiments, structural braces 410, 610, and/or 710 may be formed of and/or include metal (e.g., stainless steel, copper, aluminum, etc.) or other non-metal materials such as fiber-reinforced laminate (e.g., a glass-reinforced epoxy laminate such as FR4), alumina/ceramic, silicon carbide, sapphire, or another high strength organic material. Structural braces 410, 610, and/or 710 may be attached to device areas 303, for example, with solder or adhesive, which may include an organic adhesive such as epoxy, acrylate glue or other. In connection with attaching structural braces 410, 610, and/or 710 with an adhesive, operations may include dispensing the adhesive material in relevant regions of device areas 303, positioning the structural braces 410, 610, and/or 710 in place, and curing the adhesive, if required.

In embodiments, structural braces 410, 610, and 710 may have respective thicknesses 412, 612, and 712 and may be positioned so as not to increase a thickness (or z-height) 316 or a corresponding form-factor of electronic devices 302 in device areas 303. In these embodiments, structural braces 410, 610, and 710 may protect device areas 303 without increasing thickness or form-factor of a wearable electronic device. Moreover, incorporation of structural braces 410, 610, and 710 may incur minimal additional manufacturing costs and/or procedures. In embodiments, structural braces 410, 610, and 710 may be formed of one or more materials so as not to increase thickness 316 and may not be constrained by materials used in legacy wearable electronic devices.

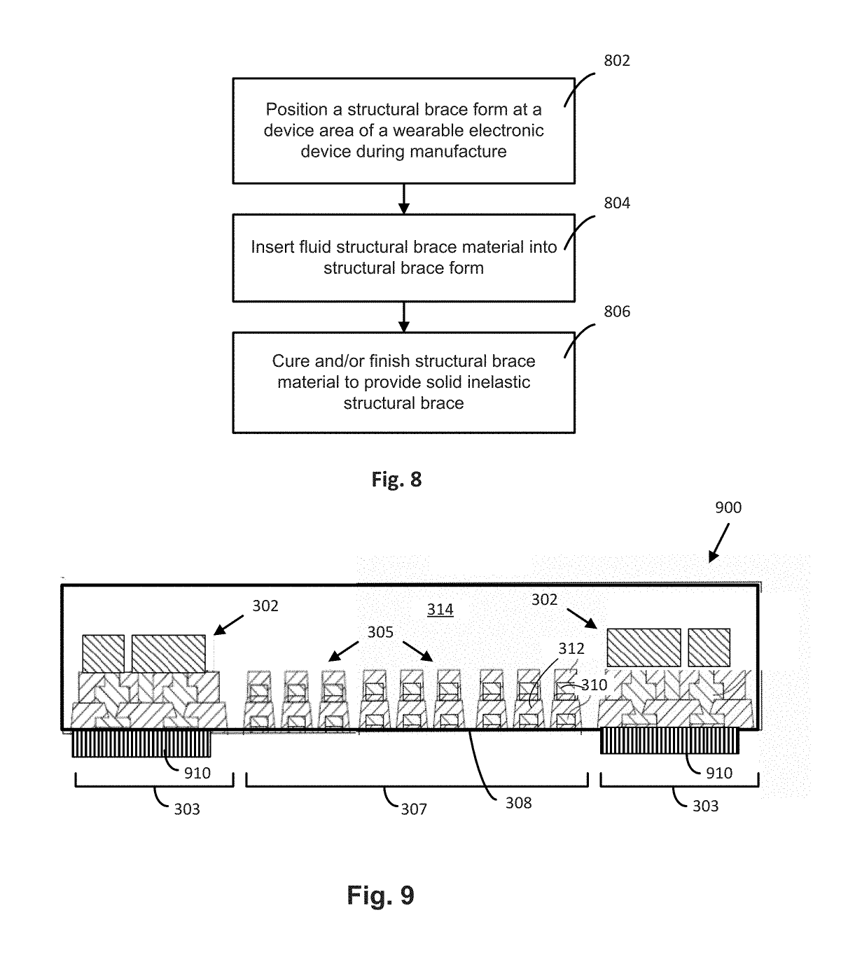

In still other embodiments, any of structural braces 410, 610, and 710 may be formed in place at devices areas 303. FIG. 8 is a flow diagram of forming a structural brace at a device area of a wearable electronic device.

At 802, a structural brace form may be positioned at a device area of a wearable electronic device during manufacture. In embodiments, the structural brace form may be positioned at the device area after positioning of electronic devices. The structural brace form may outline and form a closed volume with a configuration corresponding to any of structural braces 410, 610, or 710, for example. In embodiments, the structural brace form may be formed from metal or a fiber-reinforced laminate.

At 804, a fluid structural brace material may be inserted in the structural brace form. In an embodiment, for example, the fluid structural brace material may be or may include an underfill material and may or may not be inserted in the structural brace form during and/or in connection with application of underfill material to the electronic device during its manufacture. In embodiments, the fluid structural brace material may be or include any epoxide with suitable mechanical properties, which may include suitable inelasticity and/or lateral rigidity.

At 806, the fluid structural brace material may be cured and/or otherwise finished (e.g., dried) to provide a solid inelastic structural brace.

In embodiments, the fluid structural brace material may be cured and/or otherwise finished (e.g., dried) with the structural brace form in place so that they together may provide the solid inelastic structural brace. In other embodiments, the fluid structural brace material may be applied without a structural brace form in place. For example, an underfill material may be applied to the electronic device during its manufacture to form a structural brace, or a structural brace form, without a separate structural brace form to frame the fluid underfill material.

In some embodiments, the structural brace form may include a form for general application of underfill material during manufacture of the electronic device. In other embodiments, any of structural braces 410, 610, and 710 may be formed in place at device areas 303 without a structural brace form if, for example, the fluid structural brace material is of a consistency that may be applied to and finished at a device area 303 in the configuration of any of structural braces 410, 610, or 710 without the structural brace form.

FIG. 9 is a cross-sectional view of electronic circuit 900, which may generally correspond or be analogous to electronic circuit 300 and may include common components that are indicated by common reference numerals. Electronic circuit 900 may further include one or more structural braces 910 that may be attached to electronic circuit 900 at or along one or more device areas 303 at a bottom surface 912 of elastomeric substrate 308, outside of encapsulating elastomer 314 and opposite from electronic devices 302. Structural braces 910 may be configured like any of structural braces 410, 610, or 710, and may be inelastic and non-electronic and may reinforce the device areas 303 to reduce or prevent flexing, elongation, warpage, and/or compression that may otherwise arise in connection with stretching, flexing, and/or other elastomeric motion of electronic circuit 900 or tensile, compressive and/or lateral forces applied to electronic circuit 900. In embodiments, structural braces 910 may be applied or attached to electronic circuit 900 after its manufacturing is otherwise completed.

Embodiments described herein may reduce or prevent flexing, elongation, warpage, and/or compression of device areas of wearable electronic devices without increasing a thickness (or z-height) or corresponding form-factor of such electronic devices. In contrast, embodiments that may include thicker elastomer encapsulation over device areas, or higher modulus material encapsulating these areas, may prove insufficient, complicated to manufacture and/or compromise the maximum z-height of the electronic device. Embodiments described herein may reduce or prevent flexing, elongation, warpage, and/or compression in device areas with adversely increasing electronic device z-height and may not adversely complicate manufacturing.

Thus various example embodiments of the present disclosure have been described including, but are not limited to:

Example 1 may include an apparatus that may comprise: an elastomeric substrate; an electronic die attached to the elastomeric substrate at a first area; one or more meander traces electrically coupled to the electronic die and encapsulated in the elastomeric substrate at a second area that is adjacent to the first area; and an inelastic, non-electronic, structural brace attached to the elastomeric substrate in the first area.

Example 2 may include the apparatus of example 1, and/or any other example herein, wherein the second area extends from the first area in a first direction, the first area has a first substrate length in the first direction, and the structural brace has a first brace length in the first direction substantially the same as the first substrate length.

Example 3 may include the apparatus of example 2, and/or any other example herein, wherein the structural brace is a first structural brace and the apparatus further comprises a second inelastic, non-electronic structural brace attached to the elastomeric substrate in the first area, the second structural brace in spaced-apart and parallel relation to the first structural brace.

Example 4 may include the apparatus of example 1, and/or any other example herein, wherein the structural brace includes a frame that substantially bounds the first area.

Example 5 may include the apparatus of example 1, and/or any other example herein, wherein the structural brace has a solid brace area that substantially encompasses the first area.

Example 6 may include the apparatus of example 1, and/or any other example herein, wherein the second area extends from the first area in a first direction and the structural brace extends in the first direction from a first end adjacent the second area to an opposed second end, wherein the structural brace is thinner at the first end than at the second end.

Example 7 may include the apparatus of example 6, and/or any other example herein, wherein the structural brace has a thickness that varies continuously from the first end to the second end.

Example 8 may include the apparatus of example 1, and/or any other example herein, and may further comprise: a second electronic die attached to the elastomeric substrate at a third area, wherein the one or more meander traces have first and second ends with the first ends electrically coupled to the electronic die at the first area and the second ends electrically coupled to the second electronic die; and a second inelastic, non-electronic, structural brace attached to the elastomeric substrate in the third area.

Example 9 may include the apparatus of example 1, and/or any other example herein, wherein the electronic die is bendable and encapsulated in the elastomeric substrate at the first area.

Example 10 may include a method that may comprise: forming an elastomeric substrate; forming one or more meander traces on a first area of the elastomeric substrate; attaching an electronic die to a second area of the elastomeric substrate and forming electrical coupling between the electronic die and the one or more meander traces; forming an elastomeric encapsulant over the electronic die and the one or more meander traces; and attaching an inelastic, non-electronic structural brace to the elastomeric substrate in the second area.

Example 11 may include the method of example 10, and/or any other example herein, wherein the first area extends from the second area in a first direction, the second area has a substrate length in the first direction, and the structural brace has a brace length in the first direction substantially the same as the substrate length.

Example 12 may include the method of example 11, and/or any other example herein, wherein the structural brace is a first structural brace and the method further comprises attaching a second inelastic, non-electronic structural brace to the elastomeric substrate in the second area, the second structural brace being attached in spaced-apart and parallel relation to the first structural brace.

Example 13 may include the method of example 10, and/or any other example herein, wherein the structural brace includes a frame that substantially bounds the second area.

Example 14 may include the method of example 10, and/or any other example herein, wherein the structural brace has a solid brace area that substantially encompasses the second area.

Example 15 may include the method of example 10, and/or any other example herein, wherein the electronic die is a first electronic die and the method further comprises attaching a second electronic die to the elastomeric substrate at a third area and forming electrical coupling between the second electronic die and the one or more meander traces; forming the elastomeric encapsulant over the second electronic die, and attaching an inelastic, non-electronic second structural brace to the elastomeric substrate in the third area.

Example 16 may include the method of example 15, and/or any other example herein, wherein the first and second electronic dies are bendable.

Example 17 may include a computing device that may comprise: an elastomeric substrate; first and second electronic dies attached to the elastomeric substrate at respective first and second spaced-apart areas of the elastomeric substrate; one or more meander traces that are encapsulated in a third area of the elastomeric substrate, wherein the third area extends between the first and second areas, and the one or more meander traces have first and second ends electrically coupled to the respective first and second electronic dies; and first and second inelastic, non-electronic, structural braces attached to the elastomeric substrate in the respective first and second areas.

Example 18 may include the computing device of example 17, and/or any other example herein, wherein the first and second structural braces include frames that substantially bound the first and second areas, respectively.

Example 19 may include the computing device of example 17, and/or any other example herein, wherein the first and second structural braces have solid brace areas that substantially encompass the first and second areas, respectively.

Example 20 may include the computing device of example 17, and/or any other example herein, wherein the first and second structural braces have near ends that face toward each other and far ends that face away, and wherein the first and second structural braces are thinner at their near ends than at their far ends.

Example 21 may include the computing device of example 17, and/or any other example herein, wherein the first and second electronic dies are bendable and encapsulated in the elastomeric substrate.

It will be apparent to those skilled in the art that various modifications and variations can be made in the disclosed embodiments of the disclosed device and associated methods without departing from the spirit or scope of the disclosure. Thus, it is intended that the present disclosure covers the modifications and variations of the embodiments disclosed above provided that the modifications and variations come within the scope of any claims and their equivalents.

What is claimed is:

1. An apparatus, comprising:
an elastomeric substrate;
an electronic die attached to the elastomeric substrate at a first area;
one or more meander traces electrically coupled to the electronic die and encapsulated in the elastomeric substrate at a second area that is adjacent to the first area; and
an inelastic, non-electronic, structural brace attached to the elastomeric substrate in the first area.

2. The apparatus of claim 1, wherein the second area extends from the first area in a first direction, the first area has a first substrate length in the first direction, and the structural brace has a first brace length in the first direction substantially the same as the first substrate length.

3. The apparatus of claim 2, wherein the structural brace is a first structural brace and the apparatus further comprises a second inelastic, non-electronic structural brace attached to the elastomeric substrate in the first area, the second structural brace in spaced-apart and parallel relation to the first structural brace.

4. The apparatus of claim 1, wherein the structural brace includes a frame that substantially bounds the first area.

5. The apparatus of claim 1, wherein the structural brace has a solid brace area that substantially encompasses the first area.

6. The apparatus of claim 1, wherein the second area extends from the first area in a first direction and the structural brace extends in the first direction from a first end adjacent the second area to an opposed second end, wherein the structural brace is thinner at the first end than at the second end.

7. The apparatus of claim 6, wherein the structural brace has a thickness that varies continuously from the first end to the second end.

8. The apparatus of claim 1, further comprising:
a second electronic die attached to the elastomeric substrate at a third area, wherein the one or more meander traces have first and second ends with the first ends electrically coupled to the electronic die at the first area and the second ends electrically coupled to the second electronic die; and
a second inelastic, non-electronic, structural brace attached to the elastomeric substrate in the third area.

9. The apparatus of claim 1 wherein the electronic die is bendable and encapsulated in the elastomeric substrate at the first area.

10. A method, comprising:
forming an elastomeric substrate;
forming one or more meander traces on a first area of the elastomeric substrate;
attaching an electronic die to a second area of the elastomeric substrate and forming electrical coupling between the electronic die and the one or more meander traces;
forming an elastomeric encapsulant over the electronic die and the one or more meander traces; and
attaching an inelastic, non-electronic structural brace to the elastomeric substrate in the second area.

11. The method of claim 10, wherein the first area extends from the second area in a first direction, the second area has a substrate length in the first direction, and the structural brace has a brace length in the first direction substantially the same as the substrate length.

12. The method of claim 11, wherein the structural brace is a first structural brace and the method further comprises attaching a second inelastic, non-electronic structural brace to the elastomeric substrate in the second area, the second structural brace being attached in spaced-apart and parallel relation to the first structural brace.

13. The method of claim 10, wherein the structural brace includes a frame that substantially bounds the second area.

14. The method of claim 10, wherein the structural brace has a solid brace area that substantially encompasses the second area.

15. The method of claim 10, wherein the electronic die is a first electronic die and the method further comprises attaching a second electronic die to the elastomeric substrate at a third area and forming electrical coupling between the second electronic die and the one or more meander traces;
forming the elastomeric encapsulant over the second electronic die, and
attaching an inelastic, non-electronic second structural brace to the elastomeric substrate in the third area.

16. The method of claim 15 wherein the first and second electronic dies are bendable.

17. A computing device, comprising:
an elastomeric substrate;
first and second electronic dies attached to the elastomeric substrate at respective first and second spaced-apart areas of the elastomeric substrate;
one or more meander traces that are encapsulated in a third area of the elastomeric substrate, wherein the third area extends between the first and second areas, and the one or more meander traces have first and second ends electrically coupled to the respective first and second electronic dies; and
first and second inelastic, non-electronic, structural braces attached to the elastomeric substrate in the respective first and second areas.

18. The computing device of claim 17, wherein the first and second structural braces include frames that substantially bound the first and second areas, respectively.

19. The computing device of claim 17, wherein the first and second structural braces have solid brace areas that substantially encompass the first and second areas, respectively.

20. The computing device of claim 17, wherein the first and second structural braces have near ends that face toward each other and far ends that face away, and wherein the first and second structural braces are thinner at their near ends than at their far ends.

21. The computing device of claim 17 wherein the first and second electronic dies are bendable and encapsulated in the elastomeric substrate.
